(19) United States
(12) Patent Application Publication
(10) Pub. No.: US 2023/0082120 A1
(43) Pub. Date: Mar. 16, 2023

(54) INTEGRATED DEVICE COMPRISING PILLAR INTERCONNECTS WITH VARIABLE SHAPES

(71) Applicant: QUALCOMM Incorporated, San Diego, CA (US)

(72) Inventors: Yujen CHEN, Taichung (TW); Hung-Yuan HSU, Taichung (TW); Dongming HE, San Diego, CA (US)

(21) Appl. No.: 17/476,373

(22) Filed: Sep. 15, 2021

(51) Int. Cl. H01L 23/00; H01L 23/498

(52) U.S. Cl. CPC H01L 24/17; H01L 23/49816; H01L 23/49822; H01L 23/49838; H01L 24/16; H01L 24/11; H01L 24/13; H01L 24/14; H01L 24/05; H01L 2924/182; H01L 2224/0401; H01L 2224/17055; H01L 2224/17515; H01L 2224/1703; H01L 2224/16013; H01L 2224/16014; H01L 2224/16059; H01L 2224/16235; H01L 2224/11622; H01L 2224/13019; H01L 2224/13006; H01L 2224/13007; H01L 2224/13541; H01L 2224/1355; H01L 2224/1357; H01L 2224/1403; H01L 2224/14051; H01L 2224/14515

(57) ABSTRACT

A package comprising a substrate and an integrated device coupled to the substrate through a plurality of pillar interconnects and a plurality of solder interconnects. The plurality of pillar interconnects comprises a first pillar interconnect. The first pillar interconnect comprises a first pillar interconnect portion comprising a first width and a second pillar interconnect portion comprising a second width that is different than the first width.

### FIELD

Various features relate to integrated devices.

### BACKGROUND

A package may include a substrate and integrated devices. These components are coupled together to provide a package that may perform various electrical functions. The performance of a package and its components may depend on the quality of the joints between various components of the package. There is an ongoing need to provide packages that include secure and reliable joints between components.

### SUMMARY

Various features relate to integrated devices.

One example provides an integrated device that includes a die portion. The die portion includes a plurality of pads and a plurality of under bump metallization interconnects coupled to the plurality of pads. The integrated device includes a plurality of pillar interconnects coupled to the plurality of under bump metallization interconnects. The plurality of pillar interconnects includes a first pillar interconnect. The first pillar interconnect comprises a first pillar interconnect portion comprising a first width, and a second pillar interconnect portion comprising a second width that is different than the first width.

Another example provides a package comprising a substrate and an integrated device coupled to the substrate through a plurality of pillar interconnects and a plurality of solder interconnects. The plurality of pillar interconnects comprises a first pillar interconnect. The first pillar interconnect comprises a first pillar interconnect portion comprising a first width and a second pillar interconnect portion comprising a second width that is different than the first width.

Another example provides a method for fabricating an integrated device. The method provides a die portion. The die portion includes a plurality of pads and a plurality of under bump metallization interconnects coupled to the plurality of pads. The method forms a plurality of pillar interconnects over the plurality of under bump metallization interconnects. Forming the plurality of pillar interconnects comprises forming a first pillar interconnect portion comprising a first width, and forming a second pillar interconnect portion comprising a second width that is different than the first width.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross sectional profile view of an exemplary integrated device that includes pillar interconnects.

FIG. 2 illustrates an exemplary pillar interconnect.

FIG. 3 illustrates a cross sectional profile view of an exemplary integrated device that includes pillar interconnects.

FIG. 4 illustrates an exemplary pillar interconnect.

FIG. 5 illustrates a cross sectional profile view of an exemplary package comprising an integrated device that includes pillar interconnects, where the integrated device is coupled to a substrate.

FIG. 6 illustrates a close-up view of an exemplary package comprising an integrated device that includes pillar interconnects, where the integrated device is coupled to a substrate.

FIG. 7 illustrates a close-up view of an exemplary package comprising an integrated device that includes pillar interconnects, where the integrated device is coupled to a substrate.

FIG. 8 illustrates a close-up view of an exemplary package comprising an integrated device that includes pillar interconnects, where the integrated device is coupled to a substrate.

FIGS. 9A-9D illustrate an exemplary sequence for fabricating an integrated device that includes pillar interconnects.

FIG. 10 illustrates an exemplary flow diagram of a method for fabricating an integrated device that includes pillar interconnects.

FIG. 11 illustrate an exemplary sequence for fabricating a package comprising an integrated device that includes pillar interconnects.

FIG. 12 illustrates an exemplary flow diagram of a method for fabricating a package comprising an integrated device that includes pillar interconnects.

FIG. 13 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package that includes a substrate and an integrated device coupled to the substrate through a plurality of pillar interconnects and a plurality of solder interconnects. The plurality of pillar interconnects comprises a first pillar interconnect. The first pillar interconnect comprises a first pillar interconnect portion comprising a first width, and a second pillar interconnect portion comprising a second width that is different than the first width. In some implementations, the first width may be greater than the second width. In some implementations, the first width may be less than the second width. The different and/or varying widths may allow more surface area for the solder interconnects to couple to, thus providing a more robust and reliable joint between the integrated device and the substrate. The increased surface area may also allow more solder interconnects to be located between the first pillar interconnect and the substrate, without causing a short between neighboring interconnects of the substrate. The more robust and reliable joint helps provide a more reliable electrical path for currents and/or signals traveling between the integrated device and the substrate, which can lead to improved performances for the integrated device and the package.

### Exemplary Integrated Device Comprising a Pillar Interconnect

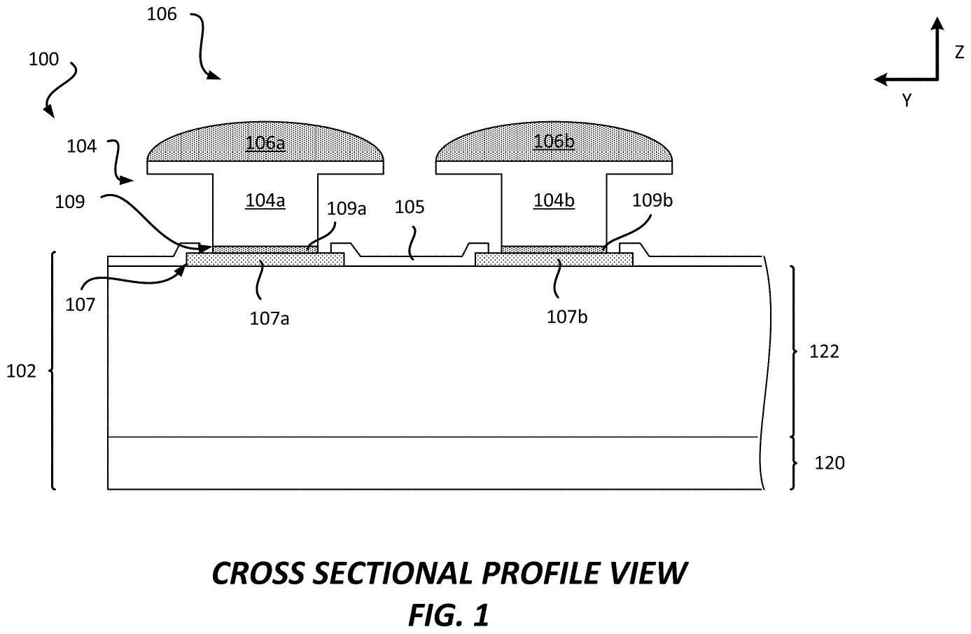

FIG. 1 illustrates a cross sectional profile view of an integrated device 100 that includes pillar interconnects with variable widths. The integrated device 100 includes a die portion 102, a plurality of pillar interconnects 104 and a plurality of solder interconnects 106. The plurality of pillar interconnects 104 is coupled to the die portion 102. The plurality of solder interconnects 106 is coupled to the plurality of pillar interconnects 104. At least one pillar interconnect from the plurality of pillar interconnects 104 includes a variable width shape. For example, at least one pillar interconnect from the plurality of pillar interconnects 104 includes a first portion with a first width and a second portion with a second width. The second width may be greater than the first width. As will be further described below, the portion of the pillar interconnect that is coupled to a solder interconnect may have a width that is greater than the portion of the pillar interconnect that is coupled to an under bump metallization interconnect. The different width creates extra surface area for solder interconnects to couple to. The different width also creates more space to accommodate more solder interconnect, while reducing the likelihood of shorting with a nearby interconnect. The extra surface area of the pillar interconnect and/or the additional volume of solder interconnect helps provide a more robust and reliable joint for the integrated device, thus providing a more robust and reliable electrical path for current(s) to and from the integrated device. The integrated device 100 may include a flip chip.

The die portion 102 includes a die substrate 120, an interconnect portion 122, a passivation layer 105, a plurality of pads 107, and a plurality of under bump metallization interconnects 109. The die substrate 120 may include silicon (Si). A plurality of cells and/or a plurality of transistors (not shown) may be formed in and/or over the die substrate 120. Different implementations may use different types of transistors, such as a field effect transistor (FET), planar FET, finFET, and a gate all around FET. In some implementations, a front end of line (FEOL) process may be used to fabricate the plurality of cells and/or transistors in and/or over the die substrate 120. The interconnect portion 122 is located over and coupled to the die substrate 120. The interconnect portion 122 may be coupled to the plurality of cells and/or transistors located in and/or over the die substrate 120. The interconnect portion 122 (e.g., die interconnect portion) may include a plurality of die interconnects (not shown) that are coupled to the plurality of cells and/or transistors. In some implementations, a back end of line (BEOL) process may be used to fabricate the interconnect portion 122.

The passivation layer 105 is located over and coupled to the interconnect portion 122. The plurality of pads 107 is located over the interconnect portion 122. The plurality of pads 107 may be coupled to die interconnects of the interconnect portion 122. In some implementations, the passivation layer 105 and/or the plurality of pads 107 may be considered part of the interconnect portion 122. In some implementations, a back end of line (BEOL) process may be used to fabricate the passivation layer 105 and the plurality of pads 107. The plurality of under bump metallization interconnects 109 is coupled to the plurality of pads 107. The plurality of under bump metallization interconnects 109 may be located over the plurality of pads 107. In some implementations, there may be additional interconnects between the plurality of pads 107 and the plurality of under bump metallization interconnects 109. For example, there may be metallization interconnects between the plurality of pads 107 and the plurality of under bump metallization interconnects 109. Examples of metallization interconnects include redistribution interconnects. In some implementations, the plurality of under bump metallization interconnects 109 may be coupled to the plurality of pads 107 through metallization interconnects (e.g., redistribution interconnects).

The plurality of pillar interconnects 104 may be coupled to the die portion 102. The plurality of pillar interconnects 104 may be coupled to the plurality of under bump metallization interconnects 109. The plurality of pillar interconnects 104 may be coupled to the die portion 102 through the plurality of under bump metallization interconnects 109. The plurality of pillar interconnects 104 may be a means for pillar interconnection. The plurality of under bump metallization interconnects 109 may be a means for under bump metallization interconnection.

The plurality of pads 107 includes a first pad 107a and a second pad 107b. The plurality of under bump metallization interconnects 109 includes a first under bump metallization interconnect 109a and a second under bump metallization interconnect 109b. The plurality of pillar interconnects 104 includes a first pillar interconnect 104a and a second pillar interconnect 104b. The plurality of solder interconnect 106 includes a first solder interconnect 106a and a second solder interconnect 106b.

The first under bump metallization interconnect 109a is coupled to the first pad 107a. The first pillar interconnect 104a is coupled to the first under bump metallization interconnect 109a. The first solder interconnect 106a is coupled to the first pillar interconnect 104a. The width of the widest part of the first pillar interconnect 104a may be greater than the width of the first under bump metallization interconnect 109a. It is noted that in some implementations, the first pillar interconnect 104a is coupled to the first under bump metallization interconnect 109a through at least one metallization interconnect. That is, at least one metallization interconnect (e.g., redistribution interconnect) may be located between the first pillar interconnect 104a and the first under bump metallization interconnect 109a.

The second under bump metallization interconnect 109b is coupled to the second pad 107b. The second pillar interconnect 104b is coupled to the second under bump metallization interconnect 109b. The second solder interconnect 106b is coupled to the second pillar interconnect 104b. The width of the widest part of the second pillar interconnect 104b may be greater than the width of the second under bump metallization interconnect 109b. It is noted that in some implementations, the second pillar interconnect 104b is coupled to the second under bump metallization interconnect 109b through at least one metallization interconnect. That is, at least one metallization interconnect (e.g., redistribution interconnect) may be located between the second pillar interconnect 104b and the second under bump metallization interconnect 109b.

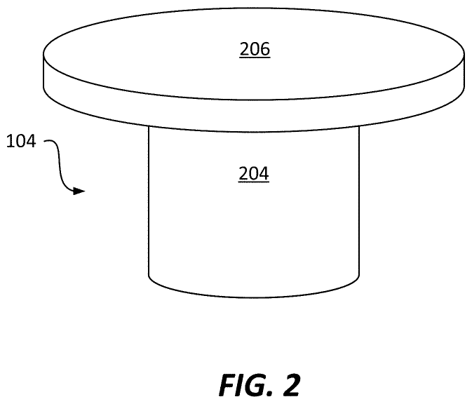

FIG. 2 illustrates an exemplary view of a pillar interconnect 104. The pillar interconnect 104 of FIG. 2 may represent any of the pillar interconnects from the plurality of pillar interconnects 104 from FIG. 1. As shown in FIG. 2, the pillar interconnect 104 includes a first pillar interconnect portion 204 and a second pillar interconnect portion 206. The first pillar interconnect portion 204 may represent a base of the pillar interconnect 104. The first pillar interconnect portion 204 may be coupled to an under bump metallization interconnect (e.g., 109a, 109b). The first pillar interconnect portion 204 includes a first width. The first width may include a first diameter. The second pillar interconnect portion 206 includes a second width. The second width may include a second diameter. The second width is different than the first width. For example, the second width may be greater than the first width. The first pillar interconnect portion 204 may be configured to be coupled to an under bump metallization interconnect. The second pillar interconnect portion 206 may be configured to be coupled to a solder interconnect.

FIG. 2 illustrates that the planar cross section area of the pillar interconnect 104 is circular. However, the pillar interconnect 104 may have a planar cross section with any shape (e.g., oval, rectangular, square). A solder interconnect (e.g., 106a, 106b) may be coupled to the second pillar interconnect portion 206. It is noted that the first pillar interconnect portion 204 and the second pillar interconnect portion 206 may be considered as one portion or as two or more separate portions. There may or may not be an interface between the first pillar interconnect portion 204 and the second pillar interconnect portion 206. The cross-sectional side profile of the pillar interconnect 104 may have a T shape.

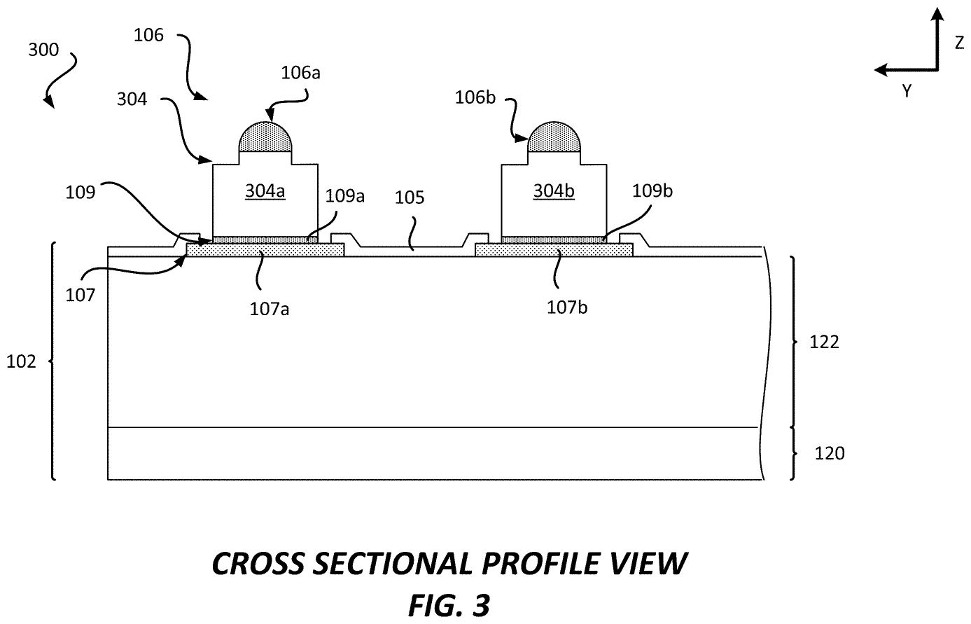

FIG. 3 illustrates a cross sectional profile view of an integrated device 300 that includes pillar interconnects with variable widths. The integrated device 300 is similar to the integrated device 100, and thus includes similar components that are configured in a similar manner as the integrated device 100. The integrated device 300 includes the die portion 102, a plurality of pillar interconnects 304 and the plurality of solder interconnects 106. The plurality of pillar interconnects 304 includes a first pillar interconnect 304a and a second pillar interconnect 304b. The plurality of pillar interconnects 304 has a different shape than the plurality of pillar interconnects 104 from the integrated device 100. The plurality of pillar interconnects 304 is coupled to the die portion 102. The plurality of solder interconnects 106 is coupled to the plurality of pillar interconnects 304. At least one pillar interconnect from the plurality of pillar interconnects 304 includes a variable width shape. For example, at least one pillar interconnect from the plurality of pillar interconnects 304 includes a first portion with a first width and a second portion with a second width. The second width may be less than the first width. The plurality of solder interconnects 106 is coupled to the portion of the plurality of pillar interconnects 304 that has a lesser width (e.g., lesser diameter).

Despite the solder interconnect being coupled to a portion of the pillar interconnect with a lesser width, the design of the pillar interconnect creates more space due to extra side surface of the pillar interconnect, to accommodate more solder interconnect, while reducing the likelihood of shorting with a nearby interconnect. The extra side surface area of the pillar interconnect and/or the additional volume of solder interconnect helps provide a more robust and reliable joint for the integrated device, thus providing a more robust and reliable electrical path for current(s) to and from the integrated device. The integrated device 300 may include a flip chip.

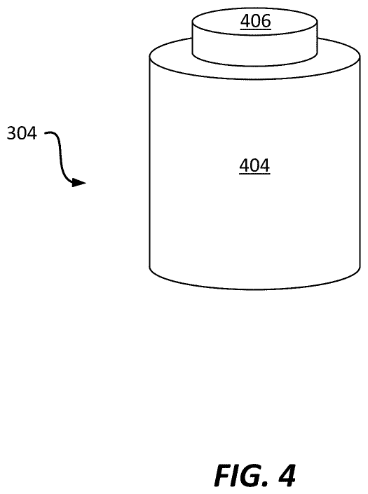

FIG. 4 illustrates an exemplary view of a pillar interconnect 304. The pillar interconnect 304 of FIG. 4 may represent any of the pillar interconnects from the plurality of pillar interconnects 304 from FIG. 3. As shown in FIG. 4, the pillar interconnect 304 includes a first pillar interconnect portion 404 and a second pillar interconnect portion 406. The first pillar interconnect portion 404 may represent a base of the pillar interconnect 304. The first pillar interconnect portion 404 may be coupled to an under bump metallization interconnect (e.g., 109a, 109b). The first pillar interconnect portion 404 includes a first width. The first width may include a first diameter. The second pillar interconnect portion 406 includes a second width. The second width may include a second diameter. The second width is different than the first width. For example, the second width may be less than the first width. The first pillar interconnect portion 404 may be configured to be coupled to an under bump metallization interconnect. The second pillar interconnect portion 406 may be configured to be coupled to a solder interconnect.

FIG. 4 illustrates that the planar cross section area of the pillar interconnect 304 is circular. However, the pillar interconnect 304 may have a planar cross section with any shape (e.g., oval, rectangular, square). A solder interconnect (e.g., 106a, 106b) may be coupled to the second pillar interconnect portion 406. There may or may not be an interface between the first pillar interconnect portion 404 and the second pillar interconnect portion 406. It is noted that the first pillar interconnect portion 404 and the second pillar interconnect portion 406 may be considered as one portion or as two or more separate portions.

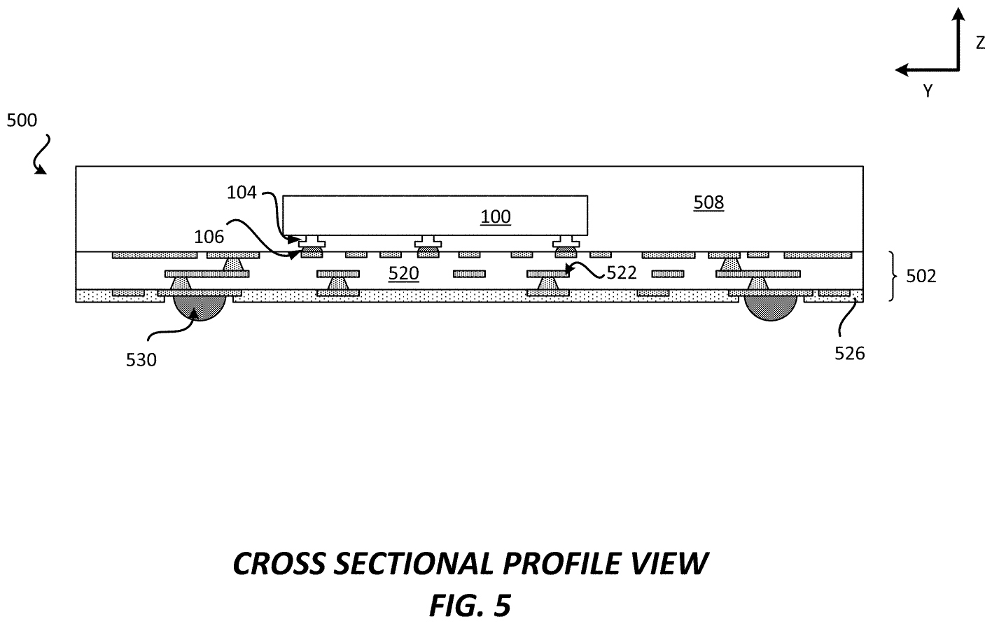

The integrated device 100 and/or the integrated device 300 may be implemented in a package. FIG. 5 illustrates a package 500 that includes a substrate 502, the integrated device 100 and an encapsulation layer 508. The substrate 502 includes at least one dielectric layer 520, a plurality of interconnects 522, and a solder resist layer 526. A plurality of solder interconnects 530 may be coupled to the plurality of interconnects 522 of the substrate 502. The integrated device 100 is coupled to a first surface (e.g., top surface) of the substrate 502 through the plurality of pillar interconnects 104 and the plurality of solder interconnects 106. The encapsulation layer 508 may be located over and/or around the integrated device 100 and/or the substrate 502. The encapsulation layer 508 may at least partially encapsulate the integrated device 100. The encapsulation layer 508 may include a mold, a resin and/or an epoxy. The encapsulation layer 508 may be a means for encapsulation. The encapsulation layer 508 may be provided by using a compression and transfer molding process, a sheet molding process, or a liquid molding process. It is noted that the integrated device 300 may be implemented in a package in a similar manner as the integrated device 100.

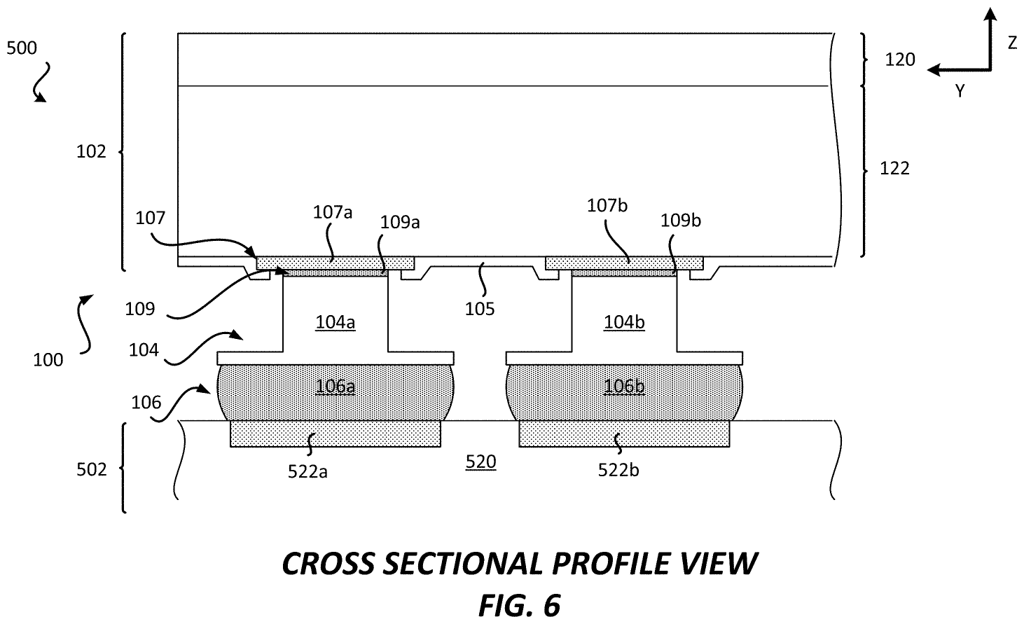

FIG. 6 illustrates a close-up view of how an integrated device may be coupled to a substrate. FIG. 6 illustrates a portion of the package 500 that includes the integrated device 100 and the substrate 502. The integrated device 100 is coupled to the substrate 502 through the plurality of pillar interconnects 104 and the plurality of solder interconnects 106.

As shown in FIG. 6, the first pillar interconnect 104a is coupled to the first solder interconnect 106a. The first solder interconnect 106a is coupled to a first interconnect 522a of the substrate 502. The first solder interconnect 106a may include an intermetallic compound (IMC) (not shown). The intermetallic compound may be formed when metal from the first interconnect 522a and/or the first pillar interconnect 104a diffuses in the solder interconnect 106a.

The second pillar interconnect 104b is coupled to the second solder interconnect 106b. The second solder interconnect 106b is coupled to a second interconnect 522b of the substrate 502. The second solder interconnect 106b may include an intermetallic compound (IMC). The intermetallic compound may be formed when metal from the second interconnect 522b and/or the second pillar interconnect 104b diffuses in the solder interconnect 106b.

FIG. 6 illustrates that the greater width of the pillar interconnect (e.g., 104a, 104b) allows the solder interconnect (e.g., 106a, 106b) to couple to more surface area. This helps provide a more robust and reliable joint. This also helps reduce stress during the coupling of the integrated device and the substrate, which helps reduce the likelihood of cracks in the package. The additional surface area in the pillar interconnect helps avoid solder cracks, since the increase solder volume makes it less likely that the solder will separate.

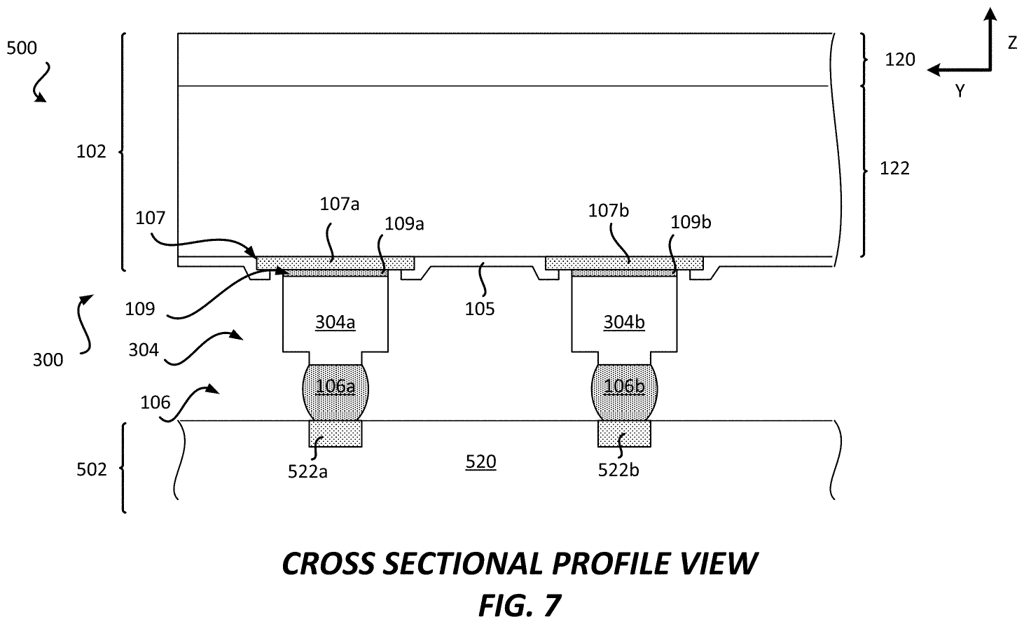

FIG. 7 illustrates a close-up view of how an integrated device may be coupled to a substrate. FIG. 7 illustrates a portion of the package 500 that includes the integrated device 300 and the substrate 502. The package 500 of FIG. 7 is similar to the package 500 of FIGS. 5-6 and may include similar components configured in a similar manner. The integrated device 300 is coupled to the substrate 502 through the plurality of pillar interconnects 304 and the plurality of solder interconnects 106.

As shown in FIG. 7, the first pillar interconnect 304a is coupled to the first solder interconnect 106a. The first solder interconnect 106a is coupled to a first interconnect 522a of the substrate 502. The first solder interconnect 106a may include an intermetallic compound (IMC) (not shown). The intermetallic compound may be formed when metal from the first interconnect 522a and/or the first pillar interconnect 304a diffuses in the solder interconnect 106a.

The second pillar interconnect 304b is coupled to the second solder interconnect 106b. The second solder interconnect 106b is coupled to a second interconnect 522b of the substrate 502. The second solder interconnect 106b may include an intermetallic compound (IMC). The intermetallic compound may be formed when metal from the second interconnect 522b and/or the second pillar interconnect 304b diffuses in the solder interconnect 106b.

FIG. 7 illustrates that the additional side surface area of the pillar interconnect (e.g., 104a, 104b) allows the solder interconnect (e.g., 106a, 106b) to couple to more surface area, since the solder interconnect may couple to side portions of the pillar interconnect. This helps provides a more robust and reliable joint. This configuration also allows narrower pillar interconnects without necessarily sacrificing the surface area, since the additional surface area may make up for some lost in the planar surface area due to the smaller width of the pillar interconnect. This allows pillar interconnects to be closer to each other without a short to occur from overflow of the solder interconnects.

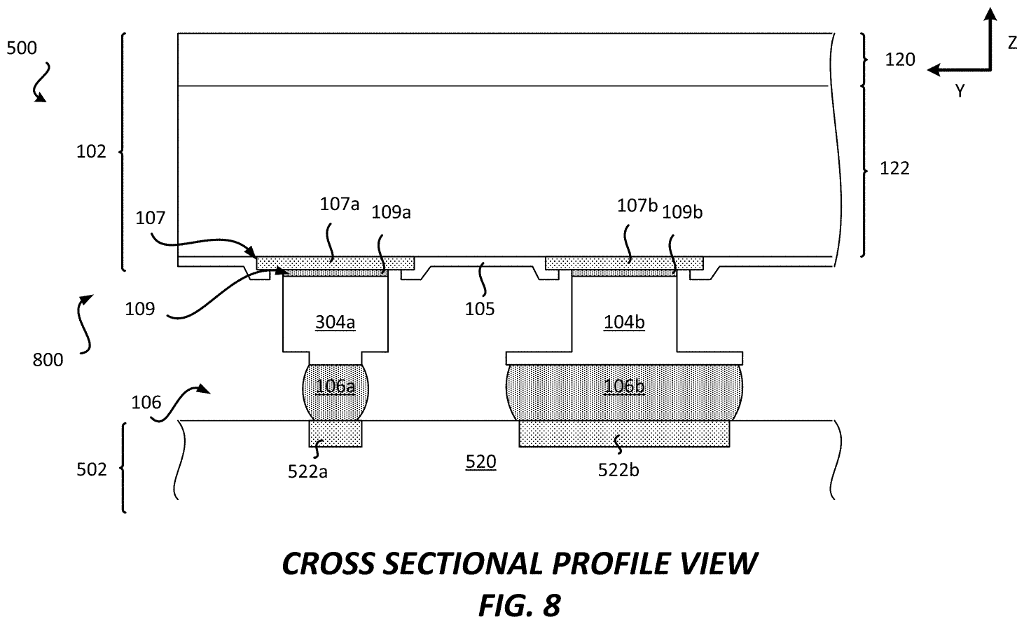

In some implementations, an integrated device may include combinations of pillar interconnects with different shapes and/or sizes. FIG. 8 illustrates a close-up view of how an integrated device may be coupled to a substrate. FIG. 8 illustrates a portion of the package 500 that includes an integrated device 800 and the substrate 502. The package 500 of FIG. 8 is similar to the packages 500 of FIGS. 5-7 and may include similar components configured in a similar manner. The integrated device 800 includes the die portion 102, the plurality of pillar interconnects 104 and the plurality of pillar interconnects 304. The integrated device 800 is coupled to the substrate 502 through the plurality of pillar interconnects 104, the plurality of pillar interconnects 304 and the plurality of solder interconnects 106.

As shown in FIG. 8, the first pillar interconnect 304a is coupled to the first solder interconnect 106a. The first solder interconnect 106a is coupled to a first interconnect 522a of the substrate 502. The first solder interconnect 106a may include an intermetallic compound (IMC) (not shown). The intermetallic compound may be formed when metal from the first interconnect 522a and/or the first pillar interconnect 304a diffuses in the solder interconnect 106a.

The second pillar interconnect 104b is coupled to the second solder interconnect 106b. The second solder interconnect 106b is coupled to a second interconnect 522b of the substrate 502. The second solder interconnect 106b may include an intermetallic compound (IMC). The intermetallic compound may be formed when metal from the second interconnect 522b and/or the second pillar interconnect 104b diffuses in the solder interconnect 106b.

In some implementations, the plurality of pillar interconnects 104 may be configured to provide electrical paths for input/output (I/O) signals to and from the integrated device 800. The smaller width and/or diameter of the plurality of pillar interconnects 104 may allow more pillar interconnects to be provided with an integrated device, thus allowing higher density routing, more connections and/or electrical paths to and from the integrated device 800. In some implementations, the plurality of pillar interconnects 304 may be configured to provide electrical paths for currents (e.g., power) to cores of the integrated device 800. The larger size of the plurality of pillar interconnects 304 helps reduce mechanical stress on the integrated device 800 and the package 500, without having to necessarily increase the size of the under bump metallization interconnect underneath the plurality of pillar interconnects 304.

An integrated device (e.g., 100, 300, 800) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filters, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device (e.g., 100) may include at least one electronic circuit (e.g., first electronic circuit, second electronic circuit, etc. . . . ). An integrated device may be an example of an electrical component and/or electrical device.

Having described an integrated device with pillar interconnects, a method for fabricating an integrated device will now be described below.

### Exemplary Sequence for Fabricating an Integrated Device Comprising a Pillar Interconnect

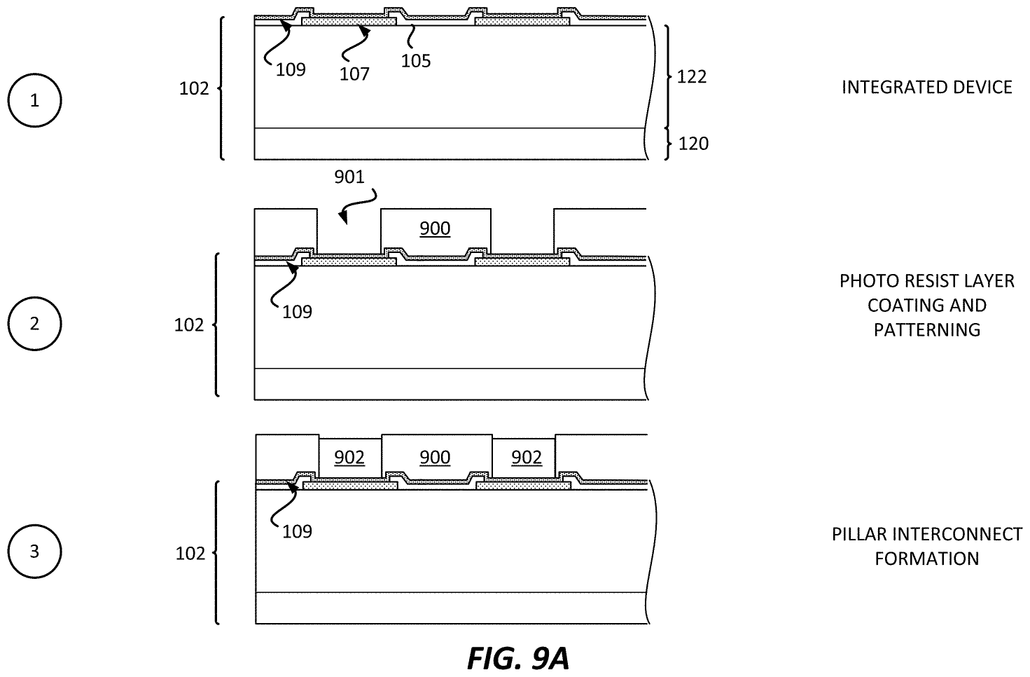

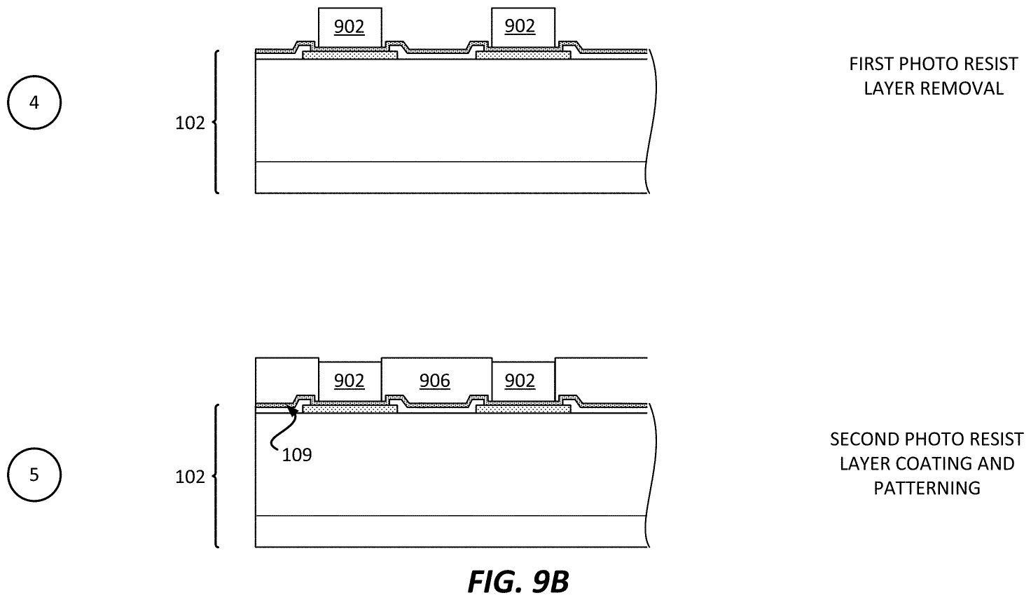

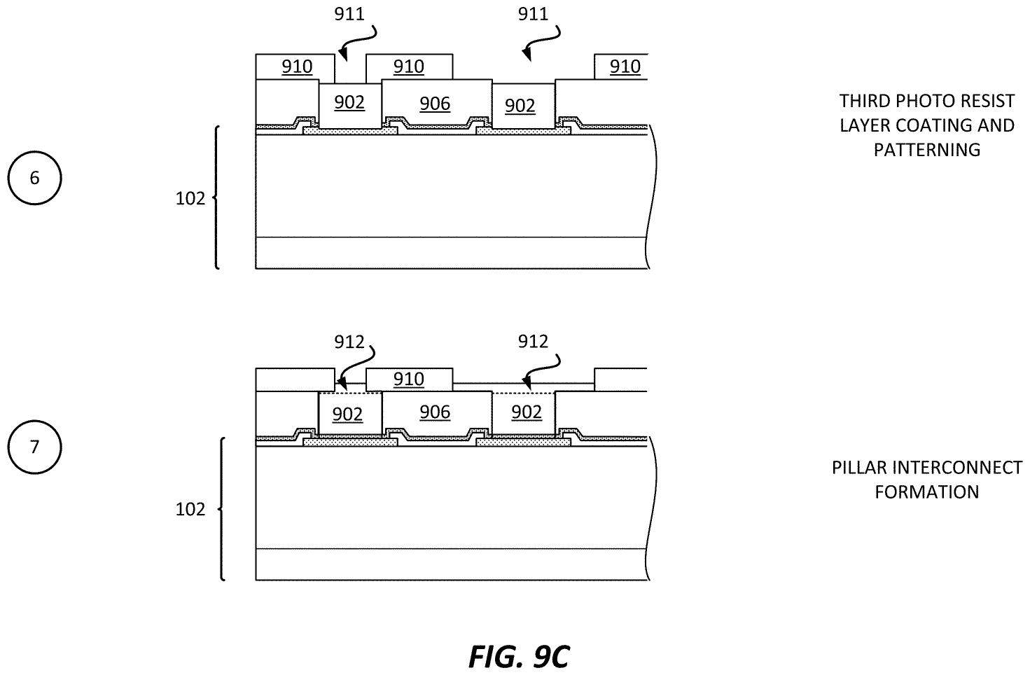

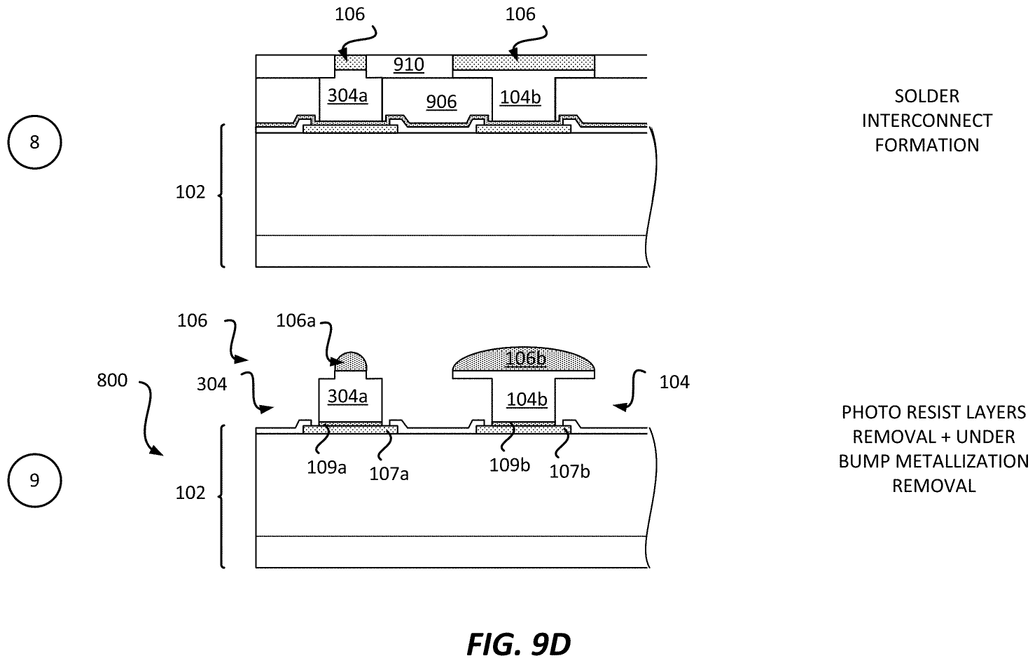

In some implementations, fabricating an integrated device includes several processes. FIGS. 9A-9D illustrate an exemplary sequence for providing or fabricating an integrated device comprising a pillar interconnect. In some implementations, the sequence of FIGS. 9A-9D may be used to provide or fabricate the integrated device 800. However, the process of FIGS. 9A-9D may be used to fabricate any of the integrated devices (e.g., 100, 300) described in the disclosure.

It should be noted that the sequence of FIGS. 9A-9D may combine one or more stages in order to simplify and/or clarify the sequence for providing or fabricating an integrated device. In some implementations, the order of the processes may be changed or modified. In some implementations, one or more of processes may be replaced or substituted without departing from the scope of the disclosure.

Stage 1, as shown in FIG. 9A, illustrates a state after a die portion 102 is provided. The die portion 102 may include a die substrate 120, an interconnect portion 122, a passivation layer 105, a plurality of pads 107 and a plurality of under bump metallization interconnects 109. The die portion 102 may include a bare die (e.g., semiconductor bare die).

Stage 2 illustrates a state after a first photo resist layer 900 is formed over the die portion 102 and patterned to include a plurality of openings 901 in the first photo resist layer 900. The first photo resist layer 900 may include a positive photo resist layer. However, in some implementations, the first photo resist layer 900 may include a negative photo resist layer. A photolithography process may be used to form and define the pattern of the first photo resist layer 900.

Stage 3 illustrates a state after pillar interconnect portions 902 are formed through the plurality of openings 901 of the first photo resist layer 900. The pillar interconnect portions 902 may be formed over the plurality of under bump metallization interconnects 109 (or under bump metallization layer). A plating process may be used to form the pillar interconnect portions 902.

Stage 4, as shown in FIG. 9B, illustrates a state after the first photo resist layer 900 is removed from the die portion 102. The first photo resist layer 900 may be removed through a development process. The first photo resist layer 900 may be removed through a rinsing process.

Stage 5 illustrates a state after a second photo resist layer 906 is formed over the die portion 102 and patterned. The second photo resist layer 906 may be formed around the pillar interconnect portions 902. The second photo resist layer 906 may include a negative photo resist layer. However, in some implementations, the second photo resist layer 906 may include a positive photo resist layer. For example, if the first photo resist layer 900 is a positive photo resist layer, the second photo resist layer 906 may be a negative photo resist layer. If the first photo resist layer 900 is a negative photo resist layer, the second photo resist layer 906 may be a positive photo resist layer. A photolithography process may be used to form and define the pattern of the second photo resist layer 906.

Stage 6, as shown in FIG. 9C, illustrates a state after a third photo resist layer 910 is formed over the second photo resist layer 906 and patterned to include a plurality of openings 911 in the third photo resist layer 910. The third photo resist layer 910 may be formed over the pillar interconnect portions 902. The third photo resist layer 910 may include a positive photo resist layer. However, in some implementations, the third photo resist layer 910 may include a negative photo resist layer. For example, if the second photo resist layer 906 is a negative photo resist layer, the third photo resist layer 910 may be a positive photo resist layer. If the second photo resist layer 906 is a positive photo resist layer, the third photo resist layer 910 may be a negative photo resist layer. Thus, in one example, the third photo resist layer 910 may have the opposite light exposure property of the second photo resist layer 906. A positive photo resist layer may have a light exposure property that degrades under light. A negative photo resist layer may have a light exposure property that strengthen under light. A photolithography process may be used to define the pattern of the third photo resist layer 910.

Stage 7 illustrates a state after a plurality of pillar interconnect portions 912 is formed through the plurality of openings 911 of the third photo resist layer 910. The plurality of pillar interconnect portions 912 may be formed over and coupled to the plurality of pillar interconnect portions 902. The plurality of pillar interconnect portions 902 and the plurality of pillar interconnect portions 912 may form and define the plurality of pillar interconnects 104 and/or the plurality of pillar interconnects 304. A plating process may be used to form the plurality of pillar interconnect portions 912. There may or may not be one or more interfaces between the pillar interconnect portions 902 formed at stage 3 and the plurality of pillar interconnect portions 912 that are formed at stage 7.

Stage 8, as shown in FIG. 9D, illustrates a state after a plurality of solder interconnects 106 is formed over the plurality of pillar interconnects 104 and/or the plurality of pillar interconnects 304 through the plurality of openings 911 of the third photo resist layer 910. In some implementations, a paste process may be used to formed the plurality of solder interconnects 106. However, the plurality of solder interconnects 106 may be formed differently.

Stage 9 illustrates a state after the third photo resist layer 910 and the second photo resist layer 906 are removed from the die portion 102. The third photo resist layer 910 and/or the second photo resist layer 906 may be removed through a development process. The third photo resist layer 910 and/or the second photo resist layer 906 may be removed through a rinsing process.

Stage 9 also illustrates a state after portions of an under bump metallization layer are selectively etched to define an under bump metallization interconnect 109a and an under bump metallization interconnect 109b. Stage 9 may also illustrate a state after the plurality of solder interconnects 106 has undergone a solder reflow process to couple the plurality of pillar interconnects 104 and/or the plurality of pillar interconnects 304. Stage 9 may illustrate an integrated device 800 that includes a die portion 102, the plurality of pillar interconnects 104, the plurality of pillar interconnects 304, and a plurality of solder interconnects 106.

The plurality of pillar interconnects 304 may include the pillar interconnect 304a. The pillar interconnect 304a may include a first portion with a first width and a second portion with a second width. The first width of the first portion of the pillar interconnect 304a may be greater than the second width of the second portion of the pillar interconnect 304a. The portion of the pillar interconnect 304a that is closer to the under bump metallization interconnect has a larger width than the portion of the pillar interconnect 304a that is farthest away (e.g., vertically farthest away) from the under bump metallization interconnect.

The plurality of pillar interconnects 104 may include the pillar interconnect 104b. The pillar interconnect 104b may include a first portion with a first width and a second portion with a second width. The first width of the first portion of the pillar interconnect 104b may be less than the second width of the second portion of the pillar interconnect 104b. The portion of the pillar interconnect 104b that is closer to the under bump metallization interconnect has a smaller width than the portion of the pillar interconnect 104b that is farthest away (e.g., vertically farthest away) from the under bump metallization interconnect.

### Exemplary Flow Diagram of a Method for Fabricating an Integrated Device Comprising a Pillar Interconnect

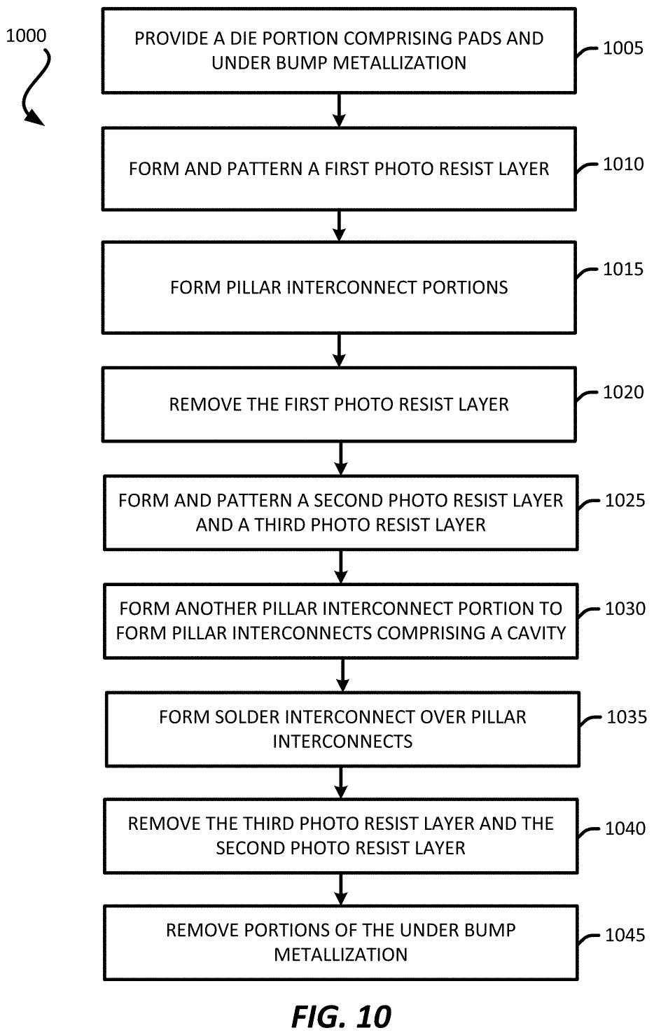

In some implementations, fabricating an integrated device includes several processes. FIG. 10 illustrates an exemplary flow diagram of a method 1000 for providing or fabricating an integrated device comprising pillar interconnects. In some implementations, the method 1000 of FIG. 10 may be used to provide or fabricate the integrated device 800 of FIG. 8 described in the disclosure. However, the method 1000 may be used to provide or fabricate any of the integrated devices (e.g., 100, 300) described in the disclosure.

It should be noted that the method of FIG. 10 may combine one or more processes in order to simplify and/or clarify the method for providing or fabricating an integrated device. In some implementations, the order of the processes may be changed or modified.

The method provides (at 1005) a die portion (e.g., 102). The die portion 102 may include a die substrate 120, an interconnect portion 122, a passivation layer 105, a plurality of pads 107 and a plurality of under bump metallization interconnects 109. The die portion 102 may include a bare die (e.g., semiconductor bare die). Stage 1 of FIG. 9A, illustrates and describes an example of providing a die portion.

The method forms (at 1010) a first photo resist layer (e.g., 900) over the die portion (e.g., 102). The method may also pattern (at 1010) the first photo resist layer (e.g., 900). A photolithography process may be used to form and define the pattern of the first photo resist layer 900. The first photo resist layer 900 may include a positive photo resist layer. However, in some implementations, the first photo resist layer 900 may include a negative photo resist layer. Stage 2 of FIG. 9A, illustrates and describes an example of forming and patterning a first photo resist layer.

The method forms (at 1015) pillar interconnects portions (e.g., 902). The pillar interconnect portions 902 may be formed over the plurality of under bump metallization interconnects 109 (or under bump metallization layer). A plating process may be used to form the pillar interconnect portions 902. The pillar interconnect portions 902 may be formed through a plurality of openings 901 of the first photo resist layer 900. Stage 3 of FIG. 9A, illustrates and describes an example of forming pillar interconnect portions.

The method removes (at 1020) the first photo resist layer (e.g., 900). The first photo resist layer 900 may be removed through a development process. The first photo resist layer 900 may be removed through a rinsing process. Stage 4 of FIG. 9B, illustrates and describes an example of removing the first photo resist layer.

The method forms (at 1025) a second photo resist layer (e.g., 906) over the die portion (e.g., 102). The method may also pattern (at 1025) the second photo resist layer (e.g., 906). The second photo resist layer may be formed around the pillar interconnect portions 902. The second photo resist layer 906 may include a negative photo resist layer. However, in some implementations, the second photo resist layer 906 may include a positive photo resist layer. A photolithography process may be used to form and define the pattern of the second photo resist layer 906. Stage 5 of FIG. 9B, illustrates and describes an example of forming and patterning a second photo resist layer.

The method also forms (at 1025) a third photo resist layer (e.g., 910) over the second photo resist layer (e.g., 906). The method may also pattern (at 1025) the third photo resist layer (e.g., 910). The third photo resist layer 910 may include a negative photo resist layer. However, in some implementations, the third photo resist layer 910 may include a positive photo resist layer. If the second photo resist layer 906 is a positive photo resist layer, the third photo resist layer 910 may be a negative photo resist layer. If the second photo resist layer 906 is a negative photo resist layer, the third photo resist layer 910 may be a positive photo resist layer. A photolithography process may be used to form and define the pattern of the third photo resist layer 910. Stage 6 of FIG. 9C, illustrates and describes an example of forming and patterning a third photo resist layer.

The method forms (at 1030) another pillar interconnect portions 912 to form a plurality of pillar interconnects 104 and/or a plurality of pillar interconnects 304. The plurality of pillar interconnects 104 and/or the plurality of pillar interconnects 304 may be formed over the plurality of under bump metallization interconnects 109 (or under bump metallization layer). The plurality of pillar interconnect portions 912 may be formed over the pillar interconnect portions 902. A plating process may be used to form the plurality of pillar interconnect portions 912. There may or may not be one or more interfaces between the pillar interconnect portions 902 formed (at 1015) and the plurality of pillar interconnect portions 912 that are formed (at 1030). Stage 7 of FIG. 9C, illustrates and describes an example of forming pillar interconnect portions to form pillar interconnects.

The method provides (at 1035) a plurality of solder interconnects (e.g., 106) over the plurality of pillar interconnects (e.g., 104, 304). The plurality of solder interconnects 106 may be formed over the plurality of pillar interconnects 104 and/or the plurality of pillar interconnects 304 through the plurality of openings 911 of the third photo resist layer 910. In some implementations, a paste process may be used to formed the plurality of solder interconnects 106. However, the plurality of solder interconnects 106 may be formed differently. Stage 8 of FIG. 9D, illustrates and describes an example of forming a plurality of solder interconnects.

The method removes (at 1040) the third photo resist layer (e.g., 910) and the second photo resist layer (e.g., 906). The third photo resist layer 910 and/or the second photo resist layer 906 may be removed through a development process The third photo resist layer 910 and/or the second photo resist layer 906 may be removed through a rinsing process. Stage 9 of FIG. 9D, illustrates and describes an example of removing the second photo resist layer.

The method may remove (at 1045) portions of an under bump metallization layer. For example, the method may selectively etch portions of the under bump metallization layer to define an under bump metallization interconnect 109a and an under bump metallization interconnect 109b. The method may also (at 1045) perform a solder reflow process to couple the plurality of solder interconnects 106 to the plurality of pillar interconnects 104 and/or the plurality of pillar interconnects 304. Stage 9 of FIG. 9D, illustrates and describes an example of removing portions of an under bump metallization layer and a solder reflow process of the plurality of solder interconnects.

The integrated devices (e.g., 100, 300, 800) described in the disclosure may be fabricated one at a time or may be fabricated together as part of one or more wafers and then singulated into individual integrated devices.

### Exemplary Sequence for Fabricating a Package Comprising an Integrated Device Comprising a Pillar Interconnect

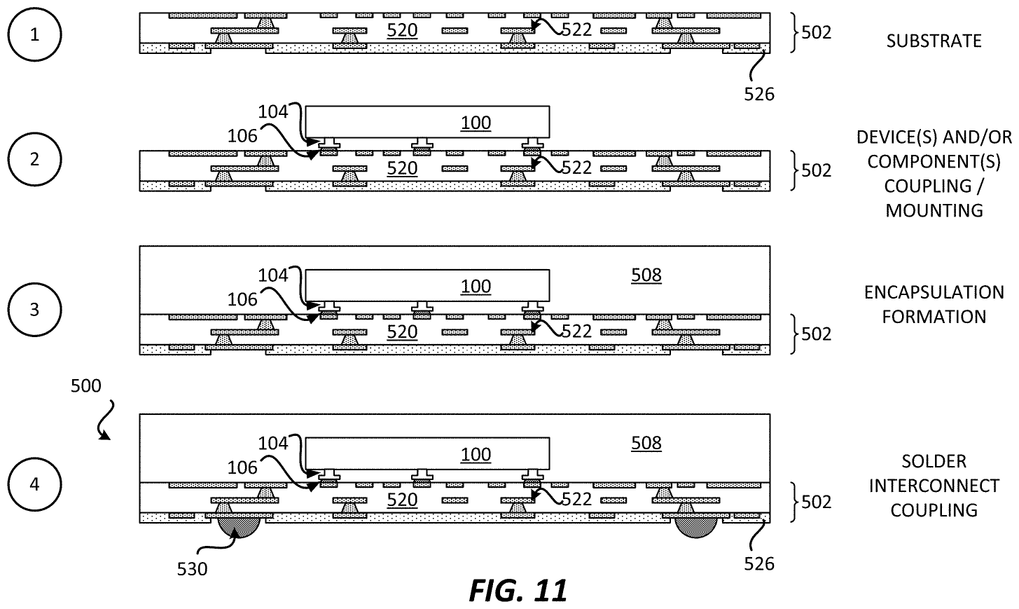

In some implementations, fabricating a package includes several processes. FIG. 11 illustrates an exemplary sequence for providing or fabricating a package that includes an integrated device comprising pillar interconnects. In some implementations, the sequence of FIG. 11 may be used to provide or fabricate the package 500 of FIG. 5. However, the process of FIG. 11 may be used to fabricate any of the packages described in the disclosure.

It should be noted that the sequence of FIG. 11 may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 11 illustrates a state after a substrate 502 is provided. The substrate 502 includes at least one dielectric layer 520, a plurality of interconnects 522 and a solder resist layer 526. Different implementations may use different substrates with different numbers of metal layers. A substrate may include a coreless substrate, a cored substrate, or an embedded trace substrate (ETS).

Stage 2 illustrates a state after the integrated device 100 is coupled to the substrate 502 through the plurality of pillar interconnects 104 and the plurality of solder interconnects 106. A solder reflow process may be used to couple the integrated device 100 to the substrate 502. FIG. 6 illustrates an example of how the integrated device 100 may be coupled to the substrate 502. Different implementations may couple different components and/or devices to the substrate 502. For example, the integrated device 300 and/or the integrated device 800 may be coupled to the substrate 502.

Stage 3 illustrates a state after an encapsulation layer 508 is provided (e.g., formed) over the substrate 502. The encapsulation layer 508 may encapsulate the integrated device 100. The encapsulation layer 508 may include a mold, a resin and/or an epoxy. A compression molding process, a transfer molding process, or a liquid molding process may be used to form the encapsulation layer 508. The encapsulation layer 508 may be photo etchable. The encapsulation layer 508 may be a means for encapsulation.

Stage 4 illustrates a state after a plurality of solder interconnects 530 is coupled to the substrate 502. A solder reflow process may be used to couple the plurality of solder interconnects 530 to the substrate 502.

### Exemplary Flow Diagram of a Method for Fabricating a Package Comprising an Integrated Device Comprising a Pillar Interconnect

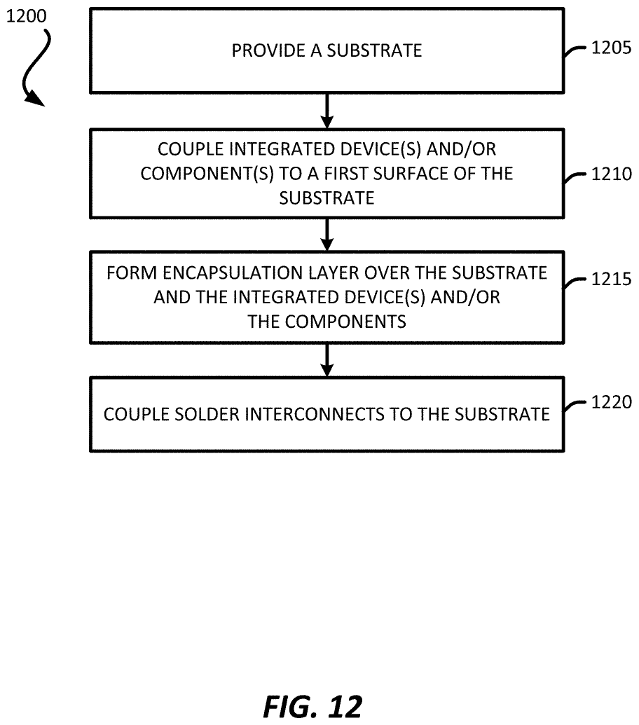

In some implementations, fabricating a package includes several processes. FIG. 12 illustrates an exemplary flow diagram of a method 1200 for providing or fabricating a package comprising an integrated device that includes pillar interconnects. In some implementations, the method 1200 of FIG. 12 may be used to provide or fabricate the package 500 of FIG. 5 described in the disclosure. However, the method 1200 may be used to provide or fabricate any of the packages (e.g., 500) described in the disclosure.

It should be noted that the method of FIG. 12 may combine one or more processes in order to simplify and/or clarify the method for providing or fabricating a package. In some implementations, the order of the processes may be changed or modified.

The method provides (at 1205) a substrate (e.g., 502). The substrate 502 may be provided by a supplier or fabricated. Different implementations may use different processes to fabricate the substrate 502. Examples of processes that may be used to fabricate the substrate 502 include a semi-additive process (SAP) and a modified semi-additive process (mSAP). The substrate 502 includes at least one dielectric layer 520, a plurality of interconnects 522, and a solder resist layer 526. The substrate 502 may include an embedded trace substrate (ETS). In some implementations, the at least one dielectric layer 520 may include prepreg layers. Stage 1 of FIG. 11, illustrates and describes an example of providing a substrate.

The method couples (at 1210) an integrated device (e.g., 100, 300, 800) a first surface of the substrate 502. For example, the integrated device 100 is coupled to a first surface (e.g., top surface) of the substrate 502. The integrated device 100 is coupled to the substrate 502 through the plurality of pillar interconnects 104 and the plurality of solder interconnects 106. A solder reflow process may be used to couple the integrated device 100 to the substrate 502. In some implementations, an integrated device may be coupled to the substrate 502 through the plurality of pillar interconnects 104, the plurality of pillar interconnects 304 and/or the plurality of solder interconnects 106. FIGS. 6-8 illustrate examples of how integrated devices may be coupled to the substrate 502. Stage 2 of FIG. 11, illustrates and describes an example of coupling an integrated device to a substrate.

The method forms (at 1215) an encapsulation layer (e.g., 508) over the substrate (e.g., 502). The encapsulation layer 508 may be provided and formed over and/or around the substrate 502 and the integrated device 100. The encapsulation layer 508 may include a mold, a resin and/or an epoxy. A compression molding process, a transfer molding process, or a liquid molding process may be used to form the encapsulation layer 508. The encapsulation layer 508 may be photo etchable. The encapsulation layer 508 may be a means for encapsulation. Stage 3 of FIG. 11, illustrates and describes an example of forming an encapsulation layer.

The method couples (at 1220) a plurality of solder interconnects (e.g., 530) to the substrate 502. A solder reflow process may be used to couple the plurality of solder interconnects 530 to the substrate 502. Stage 4 of FIG. 11, illustrates and describes an example of coupling solder interconnects to a substrate.

The packages (e.g., 500) described in the disclosure may be fabricated one at a time or may be fabricated together as part of one or more wafers and then singulated into individual packages.

### Exemplary Electronic Devices

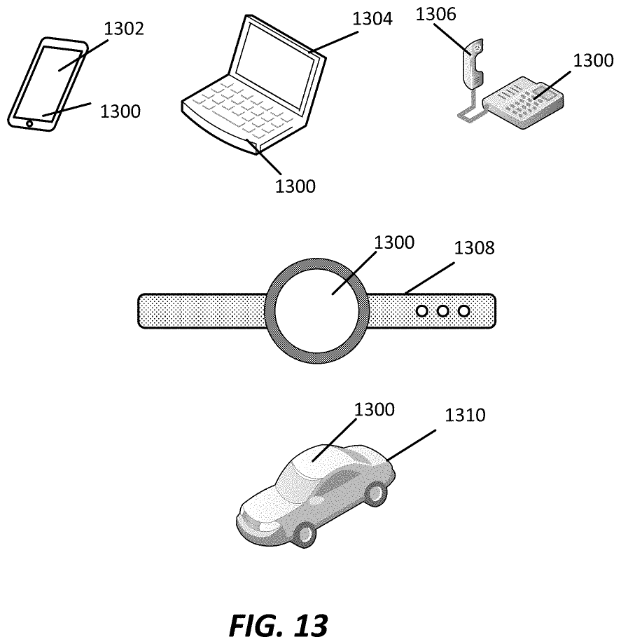

FIG. 13 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1302, a laptop computer device 1304, a fixed location terminal device 1306, a wearable device 1308, or automotive vehicle 1310 may include a device 1300 as described herein. The device 1300 may be, for example, any of the devices and/or integrated circuit (IC) packages described herein. The devices 1302, 1304, 1306 and 1308 and the vehicle 1310 illustrated in FIG. 10 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-8, 9A-9D, and/or 10-13 may be rearranged and/or combined into a single component, process, feature or function or embodied in several components, processes, or functions. Additional elements, components, processes, and/or functions may also be added without departing from the disclosure. It should also be noted FIGS. 1-8, 9A-9D, and/or 10-13 and its corresponding description in the present disclosure is not limited to dies and/or ICs. In some implementations, FIGS. 1-8, 9A-9D, and/or 10-13 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: An integrated device comprising a die portion. The die portion includes a plurality of pads and a plurality of under bump metallization interconnects coupled to the plurality of pads. The integrated device includes a plurality of pillar interconnects coupled to the plurality of under bump metallization interconnects. The plurality of pillar interconnects includes a first pillar interconnect. The first pillar interconnect includes a first pillar interconnect portion comprising a first width and a second pillar interconnect portion comprising a second width that is different than the first width.

Aspect 2: The integrated device of aspect 1, wherein the first width is greater than the second width.

Aspect 3: The integrated device of aspects 1 through 2, wherein the first pillar interconnect is configured to provide an electrical path for input/output (I/O) signals to and/or from the integrated device.

Aspect 4: The integrated device of aspects 1 through 3, wherein the first pillar interconnect portion is coupled to a first under bump metallization interconnect from the plurality of under bump metallization interconnects.

Aspect 5: The integrated device of aspect 1, wherein the first width is less than the second width.

Aspect 6: The integrated device of aspects 1 and 5, wherein the first pillar interconnect is configured to provide an electrical path for power to the integrated device.

Aspect 7: The integrated device of aspects 1 and 5 through 6, wherein the first pillar interconnect comprises a cross-sectional side profile having a T shape.

Aspect 8: The integrated device of aspects 1 and 5 through 7, wherein the plurality of pillar interconnects includes a second pillar interconnect. The second pillar interconnect includes a third pillar interconnect portion comprising a third width and a fourth pillar interconnect portion comprising a fourth width that is less than the third width.

Aspect 9: The integrated device of aspect 8, wherein the first pillar interconnect is configured to provide an electrical path for input/output (I/O) signals to and/or from the integrated device, and wherein the second pillar interconnect is configured to provide an electrical path for power to the integrated device.

Aspect 10: The integrated device of aspects 1 through 9, wherein the die portion comprises a die substrate, a plurality of transistors formed in and/or over the die substrate, and an interconnect portion located over the die substrate.

Aspect 11: A package comprising a substrate and an integrated device coupled to the substrate through a plurality of pillar interconnects and a plurality of solder interconnects. The plurality of pillar interconnects includes a first pillar interconnect. The first pillar interconnect includes a first pillar interconnect portion comprising a first width and a second pillar interconnect portion comprising a second width that is different than the first width.

Aspect 12: The package of aspect 11, wherein the first width is greater than the second width.

Aspect 13: The package of aspects 11 through 12, wherein the first pillar interconnect is configured to provide an electrical path for input/output (I/O) signals to and/or from the integrated device.

Aspect 14: The package of aspects 11 through 13, wherein the integrated device comprises a first under bump metallization interconnect, and wherein the first pillar interconnect portion is coupled to a first under bump metallization interconnect.

Aspect 15: The package of aspect 11, wherein the first width is less than the second width.

Aspect 16: The package of aspects 11 and 15, wherein the first pillar interconnect is configured to provide an electrical path for power to the integrated device.

Aspect 17: The package of aspects 11 and 15 through 16, wherein the first pillar interconnect comprises a cross-sectional side profile having a T shape.

Aspect 18: The package of aspects 11 and 15 through 17, wherein the plurality of pillar interconnects includes a second pillar interconnect. The second pillar interconnect includes a third pillar interconnect portion comprising a third width and a fourth pillar interconnect portion comprising a fourth width that is less than the third width.

Aspect 19: The package of aspect 18, wherein the first pillar interconnect is configured to provide an electrical path for input/output (I/O) signals to and/or from the integrated device, and wherein the second pillar interconnect is configured to provide an electrical path for power to the integrated device.

Aspect 20: The package of aspects 11 through 19, wherein the package is part of a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 21: A method for fabricating an integrated device. The method provides a die portion comprising a plurality of pads and a plurality of under bump metallization interconnects coupled to the plurality of pads. The method forms a plurality of pillar interconnects over the plurality of under bump metallization interconnects. Forming the plurality of pillar interconnects comprises forming a first pillar interconnect. Forming the first pillar interconnect comprises forming a first pillar interconnect portion comprising a first width, and forming a second pillar interconnect portion comprising a second width that is different than the first width.

Aspect 22: The method of aspect 21, wherein forming the plurality of pillar interconnects comprises forming and patterning a first photo resist layer over the die portion; forming a first pillar interconnect portion, removing the first photo resist layer; forming a second photo resist layer over the die portion, forming and patterning a third photo resist layer over the second photo resist layer, and forming a second pillar interconnect portion over the first pillar interconnect portion through an opening in the third photo resist layer.

Aspect 23: The method of aspect 22, wherein the third photo resist layer includes a positive photo resist layer or a negative photo resist layer.

Aspect 24: The method of aspect 23, wherein the second photo resist layer includes a positive photo resist layer or a negative photo resist layer.

Aspect 25: The method of aspect 22, wherein if the second photo resist layer includes a positive photo resist layer, the third photo resist layer includes a negative photo resist layer.

Aspect 26: The method of aspect 22, wherein if the second photo resist layer includes a negative photo resist layer, the third photo resist layer includes a positive photo resist layer.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An integrated device comprising:
a die portion comprising:
a plurality of pads; and
a plurality of under bump metallization interconnects coupled to the plurality of pads; and
a plurality of pillar interconnects coupled to the plurality of under bump metallization interconnects, wherein the plurality of pillar interconnects includes a first pillar interconnect comprising:
a first pillar interconnect portion comprising a first width; and
a second pillar interconnect portion comprising a second width that is different than the first width.

2. The integrated device of claim 1, wherein the first width is greater than the second width.

3. The integrated device of claim 1, wherein the first pillar interconnect is configured to provide an electrical path for input/output (I/O) signals to and/or from the integrated device.

4. The integrated device of claim 1, wherein the first pillar interconnect portion is coupled to a first under bump metallization interconnect from the plurality of under bump metallization interconnects.

5. The integrated device of claim 1, wherein the first width is less than the second width.

6. The integrated device of claim 5, wherein the first pillar interconnect is configured to provide an electrical path for power to the integrated device.

7. The integrated device of claim 5, wherein the first pillar interconnect comprises a cross-sectional side profile having a T shape.

8. The integrated device of claim 5, wherein the plurality of pillar interconnects includes a second pillar interconnect comprising:
a third pillar interconnect portion comprising a third width; and
a fourth pillar interconnect portion comprising a fourth width that is less than the third width.

9. The integrated device of claim 8,
wherein the first pillar interconnect is configured to provide an electrical path for input/output (I/O) signals to and/or from the integrated device, and
wherein the second pillar interconnect is configured to provide an electrical path for power to the integrated device.

10. The integrated device of claim 1, wherein the die portion comprises:
a die substrate;
a plurality of transistors formed in and/or over the die substrate; and
an interconnect portion located over the die substrate.

11. A package comprising:
a substrate; and
an integrated device coupled to the substrate through a plurality of pillar interconnects and a plurality of solder interconnects, wherein the plurality of pillar interconnects includes a first pillar interconnect comprising:
a first pillar interconnect portion comprising a first width; and
a second pillar interconnect portion comprising a second width that is different than the first width.

12. The package of claim 11, wherein the first width is greater than the second width.

13. The package of claim 11, wherein the first pillar interconnect is configured to provide an electrical path for input/output (I/O) signals to and/or from the integrated device.

14. The package of claim 11,
wherein the integrated device comprises a first under bump metallization interconnect, and
wherein the first pillar interconnect portion is coupled to a first under bump metallization interconnect.

15. The package of claim 11, wherein the first width is less than the second width.

16. The package of claim 15, wherein the first pillar interconnect is configured to provide an electrical path for power to the integrated device.

17. The package of claim 15, wherein the first pillar interconnect comprises a cross-sectional side profile having a T shape.

18. The package of claim 15, wherein the plurality of pillar interconnects includes a second pillar interconnect comprising:
a third pillar interconnect portion comprising a third width; and
a fourth pillar interconnect portion comprising a fourth width that is less than the third width.

19. The package of claim 18,
wherein the first pillar interconnect is configured to provide an electrical path for input/output (I/O) signals to and/or from the integrated device, and
wherein the second pillar interconnect is configured to provide an electrical path for power to the integrated device.

20. The package of claim 11, wherein the package is part of a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

21. A method for fabricating an integrated device, comprising:
providing a die portion comprising:
a plurality of pads; and
a plurality of under bump metallization interconnects coupled to the plurality of pads; and
forming a plurality of pillar interconnects over the plurality of under bump metallization interconnects,
wherein forming the plurality of pillar interconnects comprises forming a first pillar interconnect, and
wherein forming the first pillar interconnect comprises:
forming a first pillar interconnect portion comprising a first width; and
forming a second pillar interconnect portion comprising a second width that is different than the first width.

22. The method of claim 21, wherein forming the plurality of pillar interconnects comprises:
forming and patterning a first photo resist layer over the die portion;
forming a first pillar interconnect portion;
removing the first photo resist layer;
forming a second photo resist layer over the die portion;
forming and patterning a third photo resist layer over the second photo resist layer; and
forming a second pillar interconnect portion over the first pillar interconnect portion through an opening in the third photo resist layer.

23. The method of claim 22, wherein the third photo resist layer includes a positive photo resist layer or a negative photo resist layer.

24. The method of claim 23, wherein the second photo resist layer includes a positive photo resist layer or a negative photo resist layer.

25. The method of claim 22, wherein if the second photo resist layer includes a positive photo resist layer, the third photo resist layer includes a negative photo resist layer.

26. The method of claim 22, wherein if the second photo resist layer includes a negative photo resist layer, the third photo resist layer includes a positive photo resist layer.
